(19) United States
(12) Patent Application Publication
(10) Pub. No.: US 2026/0153545 A1
(43) Pub. Date: Jun. 4, 2026

(54) TWO-BODY SEPARATED EXTRATERRESTRIAL BODY DIELECTRIC CONSTANT PROBE AND ITS PROBING METHOD

(71) Applicant: SICHUAN AEROSPACE SYSTEM ENGINEERING INSTITUTE, CHENGDU (CN)

(72) Inventors: Xinjian WANG, CHENGDU (CN); Cheng QIAN, CHENGDU (CN); Yi ZUO, CHENGDU (CN); Lin JIANG, CHENGDU (CN); Xiandong NIE, CHENGDU (CN); Yunyun GUO, CHENGDU (CN); Lisheng DENG, CHENGDU (CN); Liying TANG, CHENGDU (CN); Zekun HA, CHENGDU (CN); Fuyu LI, CHENGDU (CN); Yong PENG, CHENGDU (CN); Hua ZHOU, CHENGDU (CN); Qingchuan YU, CHENGDU (CN); Simou WANG, CHENGDU (CN); Jianzhong LIU, CHENGDU (CN); Licheng PEI, CHENGDU (CN); Shengyuan JIANG, CHENGDU (CN)

(73) Assignee: SICHUAN AEROSPACE SYSTEM ENGINEERING INSTITUTE, CHENGDU (CN)

(21) Appl. No.: 18/973,892

(22) Filed: Dec. 9, 2024

(30) Foreign Application Priority Data
Nov. 29, 2024 (CN) 2024117320814

(51) Int. Cl. G01R 27/26; G01C 21/16; G01N 27/22

(52) U.S. Cl. CPC G01R 27/2676; G01C 21/16; G01N 27/221

(57) ABSTRACT

The present invention discloses a two-body separated extraterrestrial body dielectric constant probe and its probing method. The device comprises: a surface body being on the surface of a penetrated medium after penetration—a surface body control module is set in the surface body, which comprises a first electromagnetic pulse emission source and a first electromagnetic pulse reception source; a penetrating body, connected to the surface body through a cable, being inside the penetrated medium after penetration—a penetrating body control module is set in the penetrating body, which comprises a second electromagnetic pulse emission source and a second electromagnetic pulse reception source. The present invention, relying on a kinetic energy penetration flight capability, can help to perform in-situ probing of dielectric constants at any position of an extraterrestrial body, for example, perform a penetration analysis through orbital-based release.

### CROSS-REFERENCE TO RELATED APPLICATIONS

The application claims priority to Chinese patent application No. 2024117320814, filed on Nov. 29, 2024, the entire contents of which are incorporated herein by reference.

### TECHNICAL FIELD

The present invention relates to extraterrestrial body probing, particularly to a two-body separated extraterrestrial body dielectric constant probe and its probing method.

### BACKGROUND

For the exploration of extraterrestrial bodies, the physical characteristic parameters of extraterrestrial deep soil are crucial for inferring the evolution mechanism of the Earth, the source of the Earth's water and the distribution rule of cosmic components. In particular, the measurement of dielectric constants is closely related to the calibration of remote sensing parameters. Moreover, the measurement of dielectric constants requires an in-situ wide-area probing work to achieve more accurate results. However, those collected samples are small in size and may be contaminated.

TECPs (Thermal and Electrical Conductivity Probes) are used for some existing technologies, as shown in FIG. 1, the dielectric constant of Martian soil can be probed. During probing, the physical property probes penetrated the Martian surface soil, with Probe 1 serving as a heat source to measure the temperature changes of Physical Property Probes 2 and 3. The temperature of Probe 4 being the farthest away from the heat source was used as a reference. The length of the TECPs were 118.76 mm, the length of the physical property probes were 15 mm, and their measurement accuracy was ±10%. However, the TECPs were not intended for drilling probing, their probing depth was limited, so only relevant physical property parameters of the surface sample could be obtained.

Kinetic energy penetration probes can be used for probing with low kinetic energy requirements and high probing depth, which is convenient for in-situ in-orbit dielectric constant testing and analysis, achieving high-speed, deep, long-distance and large range probing. Kinetic energy penetration is suitable for conveniently deploying on extraterrestrial body surfaces, which, combined with the electromagnetic emission principle, achieves in-situ probing of dielectric constants.

Kinetic energy penetration probes based on some existing technologies are used according to a fixed multi-probe measurement scheme, namely, several fixed-position probe heads (electromagnetic emission probes and electromagnetic reception probes) are set on a penetration section head. During penetration landing, the penetration section head can enter a medium for dielectric constant probing under kinetic energy. However, this method has the following shortcomings: (1) during penetration, the probe heads need to enter the medium at the same time, so the contact surface is big. For the design (analog simulation), the probes must be subject to a high rigidity requirement. If the probes deform, the data will be obviously inaccurate; (2) Considering the small size of the penetration section, only dielectric constants of probe points being near to each other in the penetrated medium can be measured, so the data is not representative. This scheme provides a self-calibrating method for probing dielectric constants of large-scale extraterrestrial bodies.

### SUMMARY

The present invention is intended to overcome the shortcomings of the prior art and provide a two-body separated extraterrestrial body dielectric constant probe and its probing method.

The purpose of the present invention is achieved through the following technical solution:

On one hand, the present invention provides a two-body separated extraterrestrial body dielectric constant probe, comprising:

A surface body being on the surface of a penetrated medium after penetration-a surface body control module is set in the surface body, which comprises a first electromagnetic pulse emission source and a first electromagnetic pulse reception source;

A penetrating body, connected to the surface body through a cable, being inside the penetrated medium after penetration-a penetrating body control module is set in the penetrating body, which comprises a second electromagnetic pulse emission source and a second electromagnetic pulse reception source.

Furthermore, the first and second electromagnetic pulse emission sources can emit different forms of electromagnetic pulses, including square waves, sine waves and modulated waves.

Furthermore, the surface body is provided with a penetrating body mounting part, and the penetrating body can leave the penetrating body mounting part based on kinetic energy after penetrating a medium, thereby entering the interior of the medium.

Furthermore, the penetrating part of the penetrating body is conical, and the medium contact part of the surface body is plate-shaped.

On the other hand, the present invention provides a probing method for the two-body separated extraterrestrial body dielectric constant probe as described above, comprising:
After penetration, the surface body will be on the surface of the penetrated medium, and the penetrating body will be in the penetrated medium;
The first electromagnetic pulse emission source of the surface body control module and the second electromagnetic pulse emission source of the penetrating body control module send electromagnetic pulses, respectively;
The first electromagnetic pulse reception source of the surface body control module and the second electromagnetic pulse reception source of the penetrating body control module receive electromagnetic pulse reflected waves, respectively;
The voltage amplitude of an electromagnetic pulse reflected wave can be converted into a dielectric constant.

Furthermore, the voltage amplitude of an electromagnetic pulse reflected wave can be converted into a dielectric constant, which comprises:
Calculated voltage difference ΔV between the first voltage V1 generated by the electromagnetic pulse emitted by the second electromagnetic pulse emission source of the penetrating body control module and sensed by the first electromagnetic pulse reception source of the surface body control module and the second voltage V2 generated by the electromagnetic pulse emitted by the first electromagnetic pulse emission source of the surface body control module and sensed by second electromagnetic pulse reception source of the penetrating body control module;
Impedance Zₜ of the measured medium obtained based on the voltage difference ΔV and the emission current Iₜ,

$${Z}_{t} = \frac{Δ V}{{I}_{t}} ;$$

where, the first electromagnetic pulse emission source of the surface body control module and the second electromagnetic pulse emission source of the penetrating body control module emit alternating electrical signals with a certain frequency, and the emission current Iₜ=iₜexp (jωt), where, iₜ, ω and t refer to the current amplitude, AC frequency and time, respectively;
Measured medium capacitance C obtained based on the relationship between the imaginary part of impedance and frequency, namely

$$C = \frac{1}{ωIm \{ {Z}_{t} \}} ,$$

where, Im{Zₜ} refers to the imaginary part of Impedance Zₜ;
Dielectric constant ε obtained through Capacitance C of the measured medium, C=εfₛ; where, fₛ is a layout factor, which can be calculated by fitting a mutual inductance impedance function.

Furthermore, the mutual inductance impedance function can be calculated and fitted in the following way:
Calculating based on experimental data obtained on the ground: conducting probing tests on media with known standard dielectric constants and capacitances at different attitudes and displacements to obtain experimental layout factors at different attitudes and displacements;
Fitting the mutual inductance impedance function with impedance, displacement and attitude data as independent variables and experimental layout factors as dependent variables.

Furthermore, the displacement data can be obtained based on an acceleration integral collected by an acceleration sensor installed on the penetrating body.

The beneficial effects of the present invention are:

In an exemplary embodiment of the present invention, combined with the kinetic energy penetration flight capability, in-situ probing of dielectric constants at any position of an extraterrestrial body can be achieved, for example, a penetration analysis through orbital-based release can be performed; Moreover, electromagnetic pulse emission sources and electromagnetic pulse reception sources are set on the surface body and penetrating body, respectively, so only one probe head needs to enter the medium during penetration, reducing the contact surface of the probe, thereby reducing the possibility of deformation and even the complexity of the design (analog simulation) as well as the rigidity requirement for the probe itself; In addition, due to the distance between the surface body and penetrating body after penetrating the medium (preferably limited by cables to the farthest distance), the probed dielectric constant data of the penetrated medium can be more accurate (avoiding unrepresentative data of the penetrated medium due to a short distance).

### BRIEF DESCRIPTION OF DRAWINGS

FIG. 1 shows a schematic diagram of TECP in the prior art;

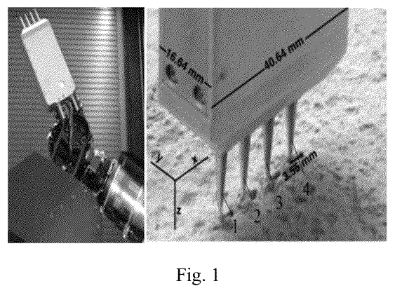

FIG. 2 shows a schematic diagram of a two-body separated extraterrestrial body dielectric constant probe provided in an exemplary embodiment of the present invention before penetration;

FIG. 3 shows a schematic diagram of a two-body separated extraterrestrial body dielectric constant probe provided in an exemplary embodiment of the present invention after penetration;

FIG. 4 shows a schematic penetration diagram of a two-body separated extraterrestrial body dielectric constant probe provided in an exemplary embodiment of the present invention;

FIG. 5 shows a flowchart of a probing method for a two-body separated extraterrestrial body dielectric constant probe provided in an exemplary embodiment of the present invention;

In the figures, 1—Surface Body, 101—Penetrating Body Mounting Part, 2—Penetrating Body, 3—Surface Body Control Module, 4—Penetrating Body Control Module, 5—Penetrated Medium, 6—Cable, 7—Electromagnetic Pulse, 8—Landing Orbit, 9—Rounding Orbit, 10—Extraterrestrial Body.

### DETAILED DESCRIPTION OF THE EMBODIMENTS

The following will provide a clear and complete description for the technical solution of the present invention in conjunction with the drawings. It is obvious that the described embodiments are only a part of those of the present invention. Based on the embodiments of the present invention, all other embodiments obtained by common technicians in the art without making creative labor shall fall within the protection of the present invention.

In the description of the present invention, it should be understood that the terms “center”, “up”, “down”, “left”, “right”, “vertical”, “horizontal”, “inside”, “outside” and other directional or positional relationships indicated are based on those shown in the drawings and only aim to facilitate the invention description and simplify the corresponding description, rather than indicate or imply that a device or an element indicated must be constructed and operated in a specified direction, and therefore should not be deemed as a limitation to the present invention. In addition, the terms “first”, “second” are only used for descriptive purposes and should not be understood as indicating or implying their relative importance.

In the description of the present invention, it should be noted that unless otherwise specified and limited, the terms “installation”, “connection”, and “junction” should be broadly understood, for example, they can be a fixed connection, a detachable connection or an integral connection, a mechanical connection or an electrical connection, a direct connection, an indirect medium-involved connection, or an internal connection between two components. For common technicians in this field, the specific meanings of the above terms in the present invention can be understood depending on the actual situations.

In addition, the technical features involved in different embodiments of the present invention described below can be combined with each other as long as they do not conflict with each other.

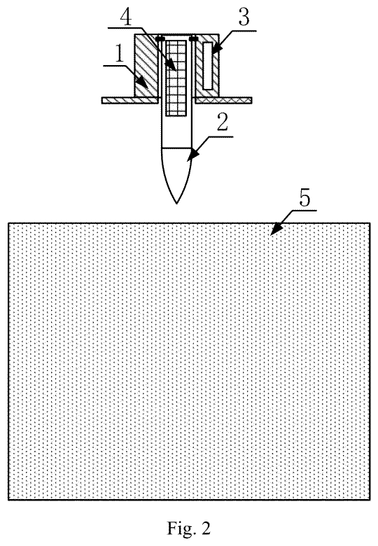

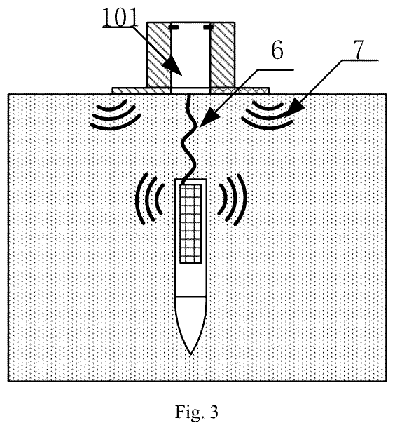

FIGS. 2 and 3 show schematic diagrams of a two-body separated extraterrestrial body dielectric constant probe provided in an exemplary embodiment of the present invention before and after penetration, which comprises:

A surface body 1 being on the surface of a medium 5 after penetrating the medium 5-a surface body control module 3 is set in the surface body 1, and the surface body control module 3 comprises a first electromagnetic pulse emission source and a first electromagnetic pulse reception source;

A penetrating body 2, connected to the surface body 1 through a cable 6, being in the medium 5 after penetrating the medium 5-a penetrating body control module 4 is set in the penetrating body 2, and the penetrating body control module 4 comprises a second electromagnetic pulse emission source and a second electromagnetic pulse reception source.

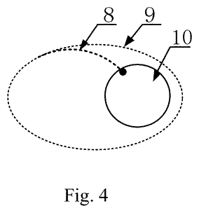

Specifically, in this exemplary embodiment, a two-body separation type extraterrestrial body dielectric constant probe are on the rounding orbit 9 and landing orbit 8 of extraterrestrial body 10 as shown in FIG. 4, which can penetrate and land on the extraterrestrial body 10 through orbit transfer, and the surface of the extraterrestrial body 10 is considered as a penetrated medium 5.

As shown in FIG. 2, before the probe lands on the medium 5 from the landing orbit 8, the surface body 1 and the penetrating body 2 are integrated. As shown in FIG. 3, the probe penetrates into the medium 5 under the action of a certain kinetic energy; when the surface body 1 and penetrating body 2 come into contact with the medium 5, under factors such as an overload, the surface body 1 is separated from the penetrating body 2; The surface body 1 is on the surface of the penetrated medium 5, and the penetrating body 2 is in the penetrated medium 5; The surface body 1 and penetrating body 2 are connected by a cable 6 between them. After penetration, a layout form as shown in FIG. 3 can be formed.

After penetration, the first electromagnetic pulse emission source of the surface body control module 3 on the surface of the penetrated medium 5 and the second electromagnetic pulse emission source of the penetrating body control module 4 in the penetrated medium 5 generate electromagnetic pulses. The electromagnetic pulse reflected waves will be received by the first electromagnetic pulse reception source of the surface body control module 3 and the second electromagnetic pulse reception source of the penetrating body control module 4, and thus the average dielectric constant at the penetrated point can be analyzed based on the principle of self-impedance and mutual-impedance.

In summary, in the exemplary embodiment of the present invention, combined with the kinetic energy penetration flight capability, in-situ probing of dielectric constants at any position of the extraterrestrial body 10 can be achieved, for example, a penetration analysis through orbital-based release can be performed; Moreover, electromagnetic pulse emission sources and electromagnetic pulse reception sources are set on the surface body 1 and penetrating body 2, respectively, so only one probe head needs to enter the medium during penetration, reducing the contact surface of the probe, thereby reducing the possibility of deformation and even the complexity of the design (analog simulation) as well as the rigidity requirement for the probe itself; In addition, due to the distance between the surface body 1 and penetrating body 2 after penetrating the medium 5 (preferably limited by a cable 6 to the farthest distance), the probed dielectric constant data of the penetrated medium 5 can be more accurate (avoiding unrepresentative data of the penetrated medium 5 due to a short distance).

More preferably, in an exemplary embodiment, the first and second electromagnetic pulse emission sources emit different forms of electromagnetic pulses 7, and the forms of electromagnetic pulses 7 include square waves, sine waves, and modulated waves.

More preferably, in an exemplary embodiment, as shown in FIG. 3, the surface body 1 is provided with a penetration body mounting portion 101, and the penetrating body 2 can leave the penetrating body mounting part 101 based on kinetic energy after penetrating the medium 5, thereby entering the interior of the medium 5.

Specifically, in this exemplary embodiment, the surface body 1 and penetrating body 2 are integrated before penetration. During penetration, the surface body 1 is still on the surface of the penetrated medium 5 due to kinetic energy, while the penetrating body 2 leaves the penetrating body mounting part 101 of the surface body 1 and enters the interior of the medium 5.

More preferably, in an exemplary embodiment, as shown in FIGS. 2 and 3, the penetrating part of the penetrating body 2 is conical, and the medium contact part of the surface body 1 is plate-shaped.

Specifically, in this exemplary embodiment, the outer diameters of the surface body 1 and penetrating body 2 are different; when the surface body 1 comes into contact with the penetrated medium 5, the two bodies that are impacted will separate from each other, and the penetrating body 2 will penetrate to a certain depth.

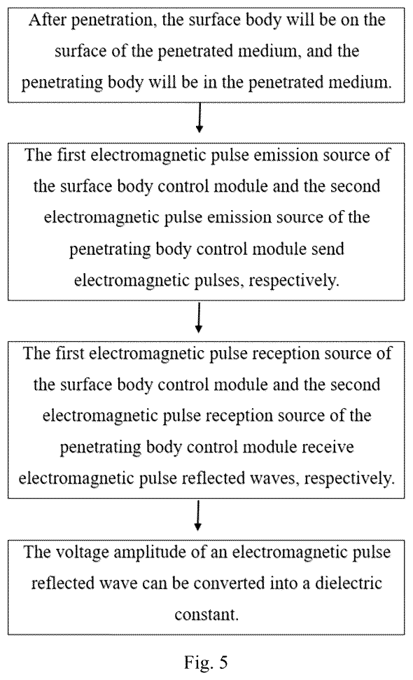

FIG. 5 shows a probing method for a two-body separated extraterrestrial body dielectric constant probe as described in FIGS. 2˜3 and provided by an exemplary embodiment of the present invention, which comprises:
After penetration, the surface body 1 will be on the surface of the penetrated medium 5, and the penetrating body 2 will be in the penetrated medium 5;
The first electromagnetic pulse emission source of the surface body control module 3 and the second electromagnetic pulse emission source of the penetrating body control module 4 send electromagnetic pulses 7, respectively;
The first electromagnetic pulse reception source of the surface body control module 3 and the second electromagnetic pulse reception source of the penetrating body control module 4 receive electromagnetic pulse reflected waves, respectively;
The voltage amplitude of an electromagnetic pulse reflected wave can be converted into a dielectric constant.

Specifically, in this exemplary embodiment, after penetration, the penetrating body control module 4 and surface body control module 3 generate electromagnetic pulses 7, and the voltage amplitude of the electromagnetic pulse reflected waves can be be processed to obtain the corresponding dielectric constant of a position of the extraterrestrial body 10.

More preferably, in an exemplary embodiment, the voltage amplitude of an electromagnetic pulse reflected wave can be converted into a dielectric constant, which comprises:
Calculated voltage difference ΔV between the first voltage V1 generated by the electromagnetic pulse emitted by the second electromagnetic pulse emission source of the penetrating body control module and sensed by the first electromagnetic pulse reception source of the surface body control module and the second voltage V2 generated by the electromagnetic pulse emitted by the first electromagnetic pulse emission source of the surface body control module and sensed by second electromagnetic pulse reception source of the penetrating body control module;
Impedance Zₜ of the measured medium obtained based on the voltage difference ΔV and the emission current Iₜ,

$${Z}_{t} = \frac{Δ V}{{I}_{t}} ;$$

where, the first electromagnetic pulse emission source of the surface body control module and the second electromagnetic pulse emission source of the penetrating body control module emit alternating electrical signals with a certain frequency, and the emission current Iₜ=iₜexp (jωt), where, iₜ, ω and t refer to the current amplitude, AC frequency and time, respectively;
Measured medium capacitance C obtained based on the relationship between the imaginary part of impedance and frequency, namely

$$C = \frac{1}{ωIm \{ {Z}_{t} \}} ,$$

where, Im{Zₜ} refers to the imaginary part of Impedance Zₜ;
Dielectric constant ε obtained through Capacitance C of the measured medium, C=εfₛ; where, fₛ is a layout factor, which can be calculated by fitting a mutual inductance impedance function.

Specifically, in this exemplary embodiment, a remote sensing measurement is performed through time-domain reflection wave analysis. After penetration, the control modules in the penetrating body and surface body will generate electromagnetic pulses. The voltage amplitude of the electromagnetic pulse reflected waves will be normalized to obtain a voltage difference before equaling to an impedance. The total impedance is inversely proportional to the dielectric constant, and the corresponding dielectric constant of a position of the extraterrestrial body can be obtained by combining geometric parameters and signal processing. Thanks to the kinetic energy penetration flight capability, in-situ probing of dielectric constants at any position on the extraterrestrial body can be performed.

More preferably, in an exemplary embodiment, the mutual inductance impedance function can be calculated and fitted in the following way:
Calculating based on experimental data obtained on the ground: conducting probing tests on media with known standard dielectric constants and capacitances at different attitudes and displacements to obtain experimental layout factors at different attitudes and displacements;
Fitting the mutual inductance impedance function with impedance, displacement and attitude data as independent variables and experimental layout factors as dependent variables.

Specifically, in this exemplary embodiment, the mutual inductance impedance function is fitted on the ground, namely, fitting multiple known data (attitude, displacement and impedance) and experimentally obtained layout factors. The fitting process can be performed in any feasible way, such as neural networks or other methods.

More preferably, in an exemplary embodiment, the displacement data can be obtained based on an acceleration integral collected by an acceleration sensor installed on the penetrating body.

It is obvious that the above embodiments are only examples for clear description and not limitations on the preference. For common technical personnel in the relevant art, other forms of changes or variations can be made on the basis of the above description. It is unnecessary and impossible to exhaustively list all embodiments here. The obvious changes or variations derived from this are still within the protection of the present invention.

What is claimed is:

1. A two-body separated extraterrestrial body dielectric constant probe, which is characterized in that it comprises:
A surface body being on the surface of a penetrated medium after penetration-a surface body control module is set in the surface body, which comprises a first electromagnetic pulse emission source and a first electromagnetic pulse reception source;
A penetrating body, connected to the surface body through a cable, being inside the penetrated medium after penetration-a penetrating body control module is set in the penetrating body, which comprises a second electromagnetic pulse emission source and a second electromagnetic pulse reception source.

2. The device according to claim 1, which is characterized in that the first and second electromagnetic pulse emission sources can emit different forms of electromagnetic pulses, including square waves, sine waves and modulated waves.

3. The device according to claim 1, which is characterized in that the surface body is provided with a penetrating body mounting part, and the penetrating body can leave the penetrating body mounting part based on kinetic energy after penetrating a medium, thereby entering the interior of the medium.

4. The device according to claim 1, which is characterized in that the penetrating part of the penetrating body is conical, and the medium contact part of the surface body is plate-shaped.

5. A probing method for the two-body separated extraterrestrial body dielectric constant probe as claimed in claim 1, which is characterized in that it comprises:
After penetration, the surface body will be on the surface of the penetrated medium, and the penetrating body will be in the penetrated medium;
The first electromagnetic pulse emission source of the surface body control module and the second electromagnetic pulse emission source of the penetrating body control module send electromagnetic pulses, respectively;
The first electromagnetic pulse reception source of the surface body control module and the second electromagnetic pulse reception source of the penetrating body control module receive electromagnetic pulse reflected waves, respectively;
The voltage amplitude of an electromagnetic pulse reflected wave can be converted into a dielectric constant.

6. The method according to claim 5, which is characterized in that the voltage amplitude of an electromagnetic pulse reflected wave can be converted into a dielectric constant, which comprises:
Calculated voltage difference ΔV between the first voltage V1 generated by the electromagnetic pulse emitted by the second electromagnetic pulse emission source of the penetrating body control module and sensed by the first electromagnetic pulse reception source of the surface body control module and the second voltage V2 generated by the electromagnetic pulse emitted by the first electromagnetic pulse emission source of the surface body control module and sensed by second electromagnetic pulse reception source of the penetrating body control module;
Impedance Zₜ of the measured medium obtained based on the voltage difference ΔV and the emission current Iₜ,
$${Z}_{t} = \frac{Δ V}{{I}_{t}} ;$$
where, the first electromagnetic pulse emission source of the surface body control module and the second electromagnetic pulse emission source of the penetrating body control module emit alternating electrical signals with a certain frequency, and the emission current Iₜ=iₜexp(jωt), where, iₜ, ω and t refer to the current amplitude, AC frequency and time, respectively;
Measured medium capacitance C obtained based on the relationship between the imaginary part of impedance and frequency, namely
$$C = \frac{1}{ωIm \{ {Z}_{t} \}} ,$$
where, Im{Z} refers to the imaginary part of Impedance Zₜ;
Dielectric constant ε obtained through Capacitance C of the measured medium, C=εfₛ; where, fₛ is a layout factor, which can be calculated by fitting a mutual inductance impedance function.

7. The method according to claim 6, which is characterized in that the mutual inductance impedance function can be calculated and fitted in the following way:
Calculating based on experimental data obtained on the ground: conducting probing tests on media with known standard dielectric constants and capacitances at different attitudes and displacements to obtain experimental layout factors at different attitudes and displacements;
Fitting the mutual inductance impedance function with impedance, displacement and attitude data as independent variables and experimental layout factors as dependent variables.

8. The method according to claim 7, which is characterized in that the displacement data can be obtained based on an acceleration integral collected by an acceleration sensor installed on the penetrating body.
